(19) United States
(12) Patent Application Publication
(10) Pub. No.: US 2006/0021572 A1
(43) Pub. Date: Feb. 2, 2006

(54) High Vacuum Plasma-Assisted Chemical Vapor Deposition System

(75) Inventor: Colin A. Wolden, Denver, CO (US)

Correspondence Address: CHRISTOPHER J. KULISH, ESQ, HOLLAND & HART LLP, P. O. BOX 8749, DENVER, CO, 80201-8749, US

(73) Assignee: COLORADO SCHOOL OF MINES, Golden, CO (US)

(21) Appl. No.: 11/161,347

(22) Filed: Jul. 29, 2005

Related U.S. Application Data
(60) Provisional application No. 60/521,996, filed on Jul. 30, 2004.

(51) Int. Cl. C23C 16/00; H05H 1/24

(52) U.S. Cl. 118/715; 427/569

(57) ABSTRACT

The invention is directed to a novel approach to thin film synthesis that is described as high vacuum plasma-assisted chemical vapor deposition (HVP-CVD). In one application of HVP-CVD, atomic oxygen and organometallic precursors are simultaneously introduced into a high vacuum chamber. Gas-phase chemistry is eliminated or substantially eliminated in the collisionless or substantially collisionless environment, allowing the surface chemistry between atomic oxygen and the precursor(s) to be interrogated directly. In preliminary work it has been observed that the presence of atomic oxygen greatly accelerates the desorption of organic ligands, facilitating oxide formation. The prominent advantages of the HVP-CVD include reduced substrate temperature, significant rates, inherent uniformity, facilitated doping, and the ability to directly study these processes in-situ with high vacuum diagnostics that are not compatible with conventional CVD technologies.

### BACKGROUND

Thin film metal oxides are critical components in numerous technological devices, including integrated circuits (IC), solar cells, light emitting diodes, UV lasers, electrochromic windows, phosphor displays, and fuel cells. The National Technology Roadmap for Semiconductors projects that next generation devices will require gate dielectrics with a thickness equivalent (t_{ox, eq})<1 nm of silicon oxide. Silicon oxide itself will be unable to satisfy these performance requirements, due to the significant amount of direct tunneling that occurs at this thickness. In response to this problem, alternative oxides with dielectric constants (κ) much greater than SiO₂ (κ˜3.8) are being pursued. These high κ materials can achieve the desired t_{ox, eq} while maintaining sufficient thickness to minimize leakage current.

The leading candidates for this application include transition metal oxides such as TiO₂, ZrO₂, HfO₂, Y₂O₃, and Ta₂O₅, as well as their alloys with SiO₂ (silicates) and Al₂O₃ (aluminates). These materials differ from SiO₂ in that they are vapor-deposited instead of thermally grown. High κ dielectric films are typically deposited by either sputtering or remote plasma-enhanced chemical vapor deposition (R-PECVD) at temperatures ranging from 300-450° C.

FIGS. 1A-1C below describe conventional chemical vapor deposition (CVD) techniques. The process conditions quoted in FIGS. 1A-1C are specific to zinc oxide synthesis, but the trends described are generally observed in all or substantially all metal oxide CVD systems. A brief description of each technique follows.

FIG. 1A illustrates a typical thermal CVD system. In this system, an oxidizer (e.g., O₂, N₂O) and an organometallic precursors, such as dimethyl zinc (DMZ), are introduced into a reaction chamber and react on a heated substrate. All chemistry, both gas-phase and surface, is thermally driven. Substrate temperatures of 400-500° C. are typically required for high quality crystalline ZnO.

FIG. 1B illustrates a plasma enhance CVD (PECVD) system. In PECVD, precursors are dissociated by electron impact reactions in the plasma. The major improvement over thermal CVD is that the substrate temperature may be reduced several hundred degrees. For crystalline ZnO a number of groups have shown that the substrate temperature may be reduced to ˜200° C. In general PECVD quality remains somewhat inferior to thermal CVD. Direct contact with the plasma exposes the growing film to ion bombardment, which can lead to defect formation and the inclusion of unwanted impurities.

FIG. 1C illustrates remote PECVD (R-PECVD), which was developed by Lucovsky and co-workers at North Carolina State University in the 1980s and has been applied extensively to metal oxide synthesis. There are two primary distinctions between PECVD and R-PECVD. First, the plasma is upstream and not in contact with the substrate. Second, the metal precursors are injected downstream through a gas dispersal ring and react with long-lived atoms and excited species from the plasma. Due to the nature of reacting flow great care must be taken in the selection of operating conditions and positioning of the dispersal ring/substrate geometry. The major improvement over PECVD is that ion bombardment is eliminated, and film quality is improved to the level enjoyed by thermal CVD. This has proven to be particularly beneficial for amorphous materials such as SiO₂, a-Si, and other oxides. R-PECVD does not offer any further temperature reduction relative to PECVD. For both zinc oxide and silicon oxide the substrate temperature remains in the 200-300° C. range for R-PECVD.

### SUMMARY OF THE INVENTION

The present invention is directed to an apparatus for implementing high vacuum, plasma assisted, chemical vapor deposition for the synthesis of a thin film on a substrate. In one embodiment, the apparatus is comprised of a reactor vessel that defines a substantial portion of a chamber suitable for the establishment of a thin film on a substrate; a support surface located within the vessel for supporting a substrate; a structure for providing a reactive species to the chamber; and a port in the vessel for conveying a volatile metal vapor into the chamber. In addition, the apparatus comprises a pump that is capable of producing a substantially collisionless environment in the chamber for gaseous substances. Potential characteristics of a collisionless environment are a pressure below about 1 mTorr or a Knudsen number greater than about 10. A collisionless environment substantially eliminates gas-phase chemistry. As a consequence, surface chemistry substantially determines the interaction between the reactive species and the volatile metal vapor. In one embodiment, the pump is capable of producing a pressure within the chamber of less than 100 μTorr.

In another embodiment, the apparatus is comprised of a reactor vessel that defines a substantial portion of a thin film deposition chamber; a support surface located within the vessel for supporting a target substrate; a structure for providing a reactive species from an interior space associated with the structure to the chamber; a first port in the reactor vessel for conveying a volatile metal vapor into the chamber; and a second port for communicating with a pump that is capable of producing a low pressure environment in the chamber for gaseous substances. The structure for providing a reactive species and the vessel are such that, during operation, a substantial pressure ratio is capable of being established between the interior space of the structure and the chamber. The pressure ratio is such that the reactive species effuses from the interior space of the structure into the chamber. In one embodiment, the pressure ratio is greater than about 10.

Yet another embodiment of the apparatus is comprised of a reactor vessel that defines a substantial portion of a thin film deposition chamber; a support surface located within the vessel for supporting a target substrate; a structure for providing a reactive species from an interior space associated with the structure to the chamber with, during operation, a substantial pressure ratio between the interior space and the chamber; a port for conveying a volatile metal vapor into the chamber; a pump that is capable of producing a pressure in the chamber of less than about 1 mTorr; and a montoring system for assessing the performance of at least one other element of the system. In one embodiment, the monitoring system comprises a reactive species monitoring system for monitoring the production of the reactive species. In another embodiment, the monitoring system comprises a mass spectrometer for monitoring the composition of constitutents within the vessel. With respect to such an embodiment that utilizes a mass spectrometer, the chamber typically must be maintained below about 0.1 mTorr.

Another embodiment of the invention is directed to a method of producing a thin film on a substrate. The method comprises providng a reactor vessel that defines a substantial portion of a chamber, a substrate located within said vessel and onto which a thin film is to be deposited, and a pressure within said vessel such that said chamber is a substantially collisionless environment with respect to gaseous substantances. The method further comprises injecting a volatile metal vapor and a reactive species into the chamber while said chamber is in said substantially collisionless state such that the volatile metal vapor and the reactive species react to produce a thin film on at least a portion of said substrate. In one embodiment, the step of providing comprises providing a heat transfer device for maintaining the substrate at a desired temperature. In another embodiment, the step of injecting comprises injecting a dopant into the chamber.

### BRIEF DESCRIPTION OF THE DRAWINGS

FIGS. 1A-1C respectively and schematically illustrate a thermal CVD system, PECVD system, and remote PECVD;

FIG. 1D is a schematic diagram of a high vacuum plasma-assisted chemical vapor deposition system (HVP-CVD);

FIG. 2 illustrates an embodiment of a HVP-CVD system;

FIGS. 3A-3C respectively are plots of the thin film deposition rate as a function dimethyl zinc (DMZ) pressure at 500° K., as a function of atomic oxygen density, as a function of temperature in the form of an Arrhenius plot for glass and silicon;

FIGS. 4A-4B respectively illustrate structural and optical properties of HYP-CVD ZnO as characterized by x-ray diffraction (XRD) pattern films on silicon and glass and UV-Vis-NIR transmission of ZnO films as a function of nitrogen doping;

FIG. 5 illustrates mass spectra obtain from Ar/O₂ and Ar/O₂/DMZ mixtures with and without plasma activation;

FIG. 6A illustrates the thermal decomposition of DMZ at various temperatures;

FIG. 6B illustrates the atomic oxygen mediated decomposition of DMZ with a fixed temperature range of 290-500° K. in an HVP-CVD system.

### DETAILED DESCRIPTION

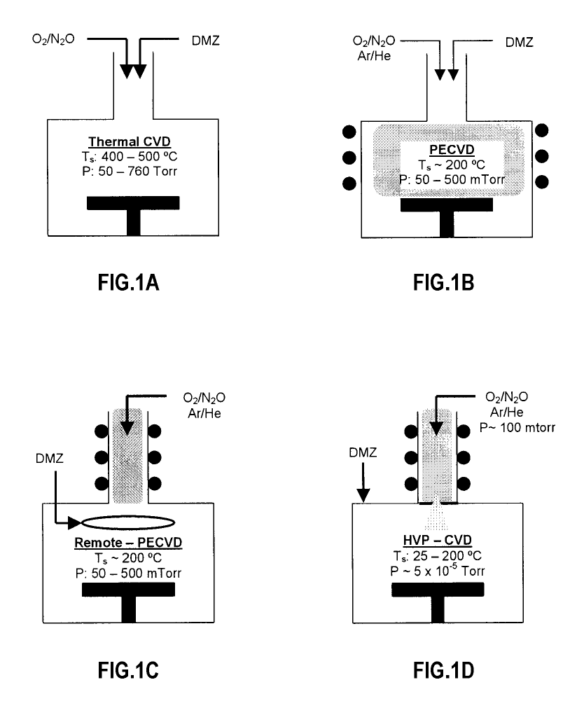

FIG. 1D is a schematic of a high vacuum, plasma-assisted, chemical vapor deposition (HVP-CVD) system. Like remote PECVD, the plasma is removed from the substrate in HVP-CVD, eliminating or substantially eliminating ion bombardment. Unlike remote PECVD, the reactive species effuse from the plasma into a high vacuum deposition chamber under substantially collisonless conditions. A high vacuum for purposes of HVP-CVD is below about 1 mTorr. In the illustrated embodiment, the high vacuum is approximately 5×10⁻⁵ Torr. The organometallic precursor is also introduced into the high vacuum chamber. All other CVD techniques operate under continuum flow conditions where extensive gas-phase collisions and gas-phase chemistry occur. The most important distinction of HVP-CVD is that gas-phase chemistry is eliminated or substantially eliminated, and precursor decomposition occurs exclusively or substantially through surface-mediated routes. It is in many ways similar to plasma-assisted molecular beam epitaxy (P-MBE), with at least the exception that the metal is introduced as an organometallic vapor instead of being supplied by an elemental effusion source.

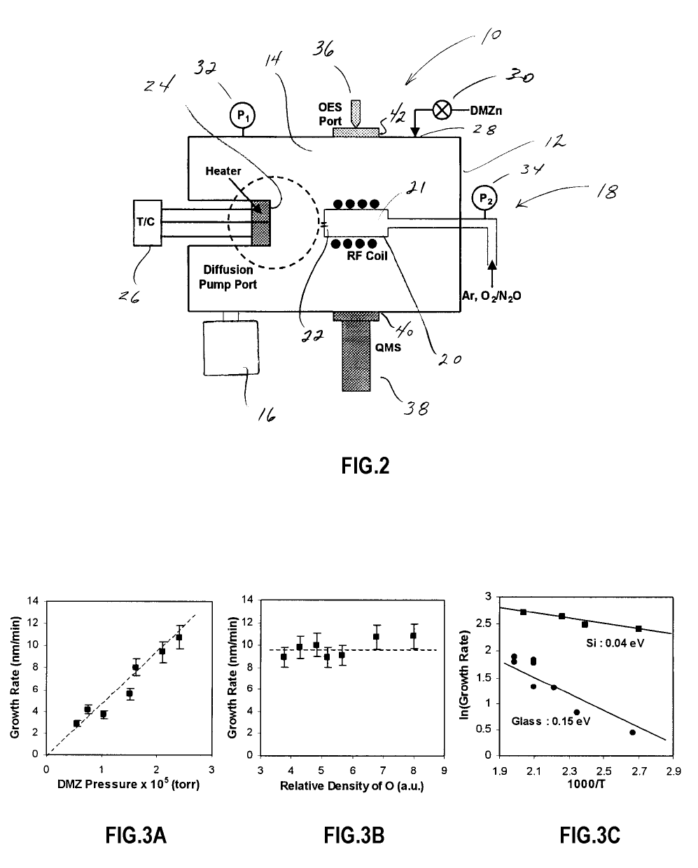

An embodiment of an HVP-CVD for zinc oxide synthesis from dimethyl zinc (DMZ) is now described. FIG. 2 shows a schematic cross-section of an embodiment of an HVP-CVD reactor 10. The reactor 10 is a vacuum grade, stainless steel vessel 12 that substantial defines a chamber 14 that is exhausted by a diffusion pump 16 to a base pressure of 10⁻⁷ torr. An inductively coupled plasma (ICP) source 18 is used to produce atomic oxygen. The ICP tube 20, which defines a space 21 within which a plasma that includes atomic oxygen is produced, is supplied with Ar, O₂, and/or N₂O gas metered using electronic mass flow controllers (MFCs). The plasma is ignited with an RF power supply operating at 13.56 MHz and coupled using an automatic match network. Reactive products effuse from a 0.125-inch hole 22 directed towards a substrate under near choked flow conditions (i.e., gas atoms or molecules enter the chamber 14 relatively close to the speed of sound). The substrate is supported on a heat-able surface 24 whose temperature is controlled with a thermocouple 26. DMZ is introduced into the chamber directly, via port 28, without carrier gas and using a calibrated metering valve 30. The pressure in the film growth chamber is measured with an ionization gauge (P₁) 32, and the pressure in the plasma tube is measured with an upstream convection gauge (P₂) 34. Under typical growth conditions the ICP pressure is P₂˜100 mtorr and the deposition chamber is P1˜10⁻⁵ torr. The substantial pressure difference (>10³) between the ICP source and the deposition chamber 14 ensures that the two regimes are effectively decoupled.

The ICP source 18 performance and the composition in the deposition chamber 14 are monitored in real time using an optical emission spectrometer (OES) 36 and quadrupole mass spectrometer (QMS) 38. In one embodiment, emission from the plasma is collected by a fiber optic cable and analyzed using an Ocean Optics SD2000 optical emission spectrometer. A Stanford Research Systems RGA was used to analyze the composition of the deposition chamber 14. The QMS has a range of 2-300 amu and a resolution of 0.1 amu. The QMS is mounted on a port 40 directly opposite of an OES port 42 and analyzes the chamber composition directly, so there are no complications associated with sampling and differential pumping. The ICP source 18 is encircled by a grounded Faraday gauge of copper mesh, allowing simultaneous operation of the plasma and the QMS with minimal interference. The atomic oxygen density was varied by adjusting plasma power and/or substitution of N₂O for O₂. QMS and OES measurements indicated that the atomic oxygen increased linearly with plasma power, and decreased linearly with N₂O substitution. Corning 1737 glass and p-type silicon have been used as substrates. Other substrates are also feasible. In an embodiment, the substrates were clamped to the heat-able surface 24 (in the form of a resistively heated susceptor) whose temperature was maintained by a thermocouple 26 (in the form of a PID controller) from 290-500 K. The structural, optical, and electrical properties of the deposited films were quantified.

It should be appreciated that other systems that satisfy the requirements for an HVP-CVD system are feasible and, if necessary, can be adapted to deposit different metal oxide thin films. For example, other mechanisms for producing atomic oxygen or other reactive species (e.g., atomic hydrogen and atomic nitrogen) include capacitively-coupled plasma sources, thermal plasma sources, photolysis plasma sources, helicon resonators, thermal sources, and photolysis sources. The hole 22 associated with the plasma source 20 can be larger or smaller, provided the space 21, during operation, can be maintained at a pressure that substantially decouples the space 21 from the chamber 14. Further, multiple holes can be utilized, provided substantially decoupling of the space 21 from the chamber 14 is capable of being maintained during operation of the reactor 10. In addition, an HVP-CVD system can employ different configurations of the elements of the system are feasible. For example, a portion of the vessel 12 with an appropriately sized hole can be used to separate the chamber 14 from a plasma source that is located outside of the vessel 12, rather than inside the vessel, as shown in FIG. 2. In some HVP-CVD systems, the establishment of a suitable metal oxide thin film may be feasible at room temperature. In such cases, the structure associated with heating of the substrate may be eliminated. It should also be appreciated that an OES 32 or other device capable of monitoring the density of the atomic oxygen produced by the plasma source 20 can be used in a feedback system to control the density of the atomic oxygen and any associated dopant. Similarly, the QMS 34 or other device capable of monitoring the composition of the chamber 14 can be used in a feedback system to alter the deposition of the metal oxide thin film on a substrate.

It should be further appreciated that a volatile metal vapor other than an organometallic vapor can be injected into the chamber 14 to establish a metal oxide thin film. For example, metal halides and metal hydrides are feasible. Further, the production of atomic oxygen is not limited to the source materials of O₂ and/or N₂O. Other materials from which atomic oxygen can be produced comprise O₃, H₂O, and volatile gases from which atomic oxygen can be readily derived.

It should also be appreciated that an HVP-CVD is capable of being utilized to produce thin films other than metal oxide thin films. For instance, HVP-CVD is capable of being used to produce thin films of a metal, a carbide, or a nitride. When used to produce other types of thin films, the reactive species and precursor applied to the HVP-CVD are adjusted accordingly. For example, if atomic hydrogen is required, H₂ or some other compound from which atomic hydrogen can be derived is applied to a plasma source or other source that is capable of producing the atomic hydrogen. Similarly, if atomic nitrogen is required, ammonia or some other compound from which atomic nitrogen can be derived is applied to a plasma source or other device capable of producing the atomic nitrogen. With respect to precursors, it should also be appreciated that the precursor is not limited to contributing a single element to the thin film that is to be established on a substrate (as with DMZ). The precursor may contribute two or more elements to the thin film. For instance, the precursor may contribute two metals to the thin film.

Results from ZnO System. Crystalline ZnO films have been successfully deposited over a temperature range from 290-500 K. The deposition rate dependence on DMZ, atomic O, and temperature are shown in FIG. 3. The deposition was found to be first order on DMZ (FIG. 3A) and independent of atomic O (FIG. 3B). The rates themeselves are significant, greater than or comparable to that obtained in P-MBE or R-PECVD. The rates are consistent with a DMZ surface reaction probability near unity. The Arrhenius plots (FIG. 3C) indicate that the deposition is weakly activated, with apparent activation energies on both substrates near zero but positive (˜0.1 eV). An important consequence of the small activation energy is that highly oriented ZnO films were obtained at room temperature. This is a nearly 200° C. reduction over what has been achieved with PECVD.

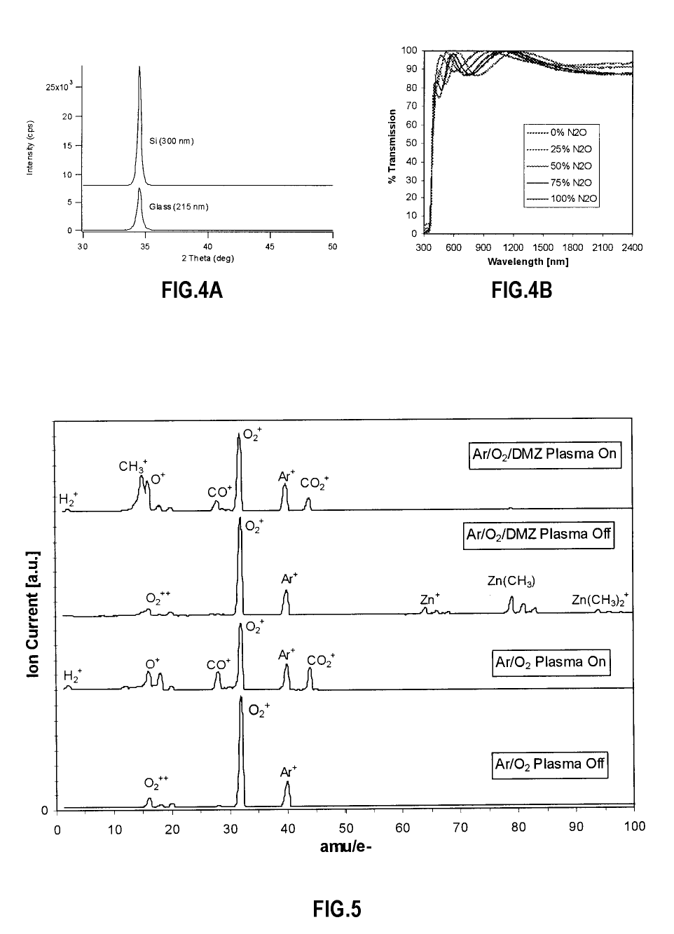

The films have excellent structural and optical properties as shown in FIG. 4. FIG. 4A shows XRD patterns obtained on both silicon and on glass. In all cases, the films displayed a strong orientation in the (002) direction, which is preferred for structural and optical applications. The films deposited with N₂O were found to be nitrogen doped as determined by X-ray photoelecton spectroscopy (XPS). The nitrogen content varied linearly up to 4% when only N₂O was used in the ICP source. This itself is another significant achievement of HVP-CVD. Nitrogen doping has been shown to be the most successful approach to forming p-type ZnO, which enables blue and UV light emitting devices. Nitrogen doping of ZnO has been achieved predominantly using P-MBE systems. One exception was thermal CVD when NO was employed as the sole oxiding gas. A similar situation is believed to be occuring here. The QMS data indicates that N₂O is completely dissociated in the ICP source, producing significant amounts of N₂, NO, O and O₂. Both O and NO are believed to contribute to film growth, with the latter leading to N-doping. Nitrogen doping has a minimal impact on structural or optical properties. As shown in FIG. 4B the optical transmission is only slightly impacted. The band gap absorption is shifted slightly into the visible, but all films displayed excellent average visible transmission value between 88-93%. It should be appreciated that the HVP-CVD system can be used to deposit metal oxide thin films with other dopants, such as hydrogen, sulfur, fluorene, chlorine, halides, other metals, and the like.

Perhaps the best aspect of HVP-CVD is its ability to investigate the chemistry directly using QMS and other high vacuum diagnostics. FIG. 5 shows four spectra that illustrate the processes occuring in the system. The bottom two spectra were obtained when an O₂/Ar mixture was supplied through the ICP device with and without plasma operation. The molecular oxygen signal drops with plasma ignition, and the atomic O produced reacts with residual carbon in the system to produce significant amounts of CO and CO₂. The top two spectra were taken when DMZ is bled into the system, again with and without ICP activation. Without the plasma nothing happens, as the DMZ cracking pattern is identical to the one observed with only Ar/DMZ mixtures. With plasma operation the DMZ is almost completely consumed, resulting in a significant increase in the signal at m/e=15, which is atrributed to unreacted methyl groups desorbing from the surface. Very little else was observed to occur. The H₂, CO, and CO₂ signals are similar to the case of plasma operation without DMZ. No gas-phase Zn or ZnO was observed, and it is assumed that Zn is completely consumed on the substrate and the walls of the reactor. Since ZnO deposition was observed at room temperature, the entire reactor surface may act as a substrate in the presence of atomic oxygen. It should be appreciated that when HVP-CVD is used with other precursors, the chemistry may operate quite differently from the DMZ chemistry.

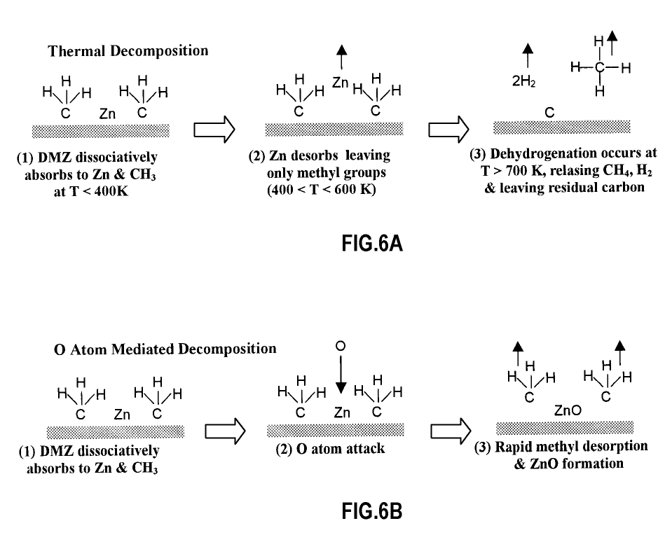

It is of interest to compare the behavior of HVP-CVD system with the thermal decomposition of DMZ. The results of a surface science investigation of DMZ reaction by Reuters and Vohs are illustrated in FIG. 6A. They observed that DMZ dissociatively absorbs on silicon at temperatures<400° K. Upon heating Zn desorbs first, leaving only methyl groups on the surface by T=600° K. Dehydrogenation reactions were observed to commence at T>700° K., leading to desorption of methane, hydrogen, and the deposition of residual carbon on the surface. As shown in the spectra of FIG. 5, which were obtained at T<500° K., the surface chemistry of DMZ is very different in the presence of atomic oxygen. The HVP-CVD process is contrasted with thermal decomposition in FIG. 6B. It is assumed that the first step remains dissociative absorption. However, the presence of atomic oxygen both readily forms ZnO and accelerates methyl desorption without further reaction. No carbon incorporation was observed in the films, as evidenced by the extremely high transmission shown in FIG. 4B. The ability of reactive species to alter surface chemistry has been observed before. In surface science studies of trimethyl gallium decomposition it was observed that the presence of arsine greatly accelerated methyl desorption as well. The thermal decomposition of organometallic precursors has been studied in great detail due to their role in the synthesis of III-V and II-VI compound semiconductors. To summarize, the observed benefits from HVP-CVD are: (a) reduced deposition temperature. In the case of ZnO crystalline films are obtained at room temperature; (b) significant deposition rates are achieved, indicating high precursor utilization; (c) new routes to doping—by mixing N₂O and O₂ in the ICP source controlled nitrogen doping has been achieved from 0-4% as measured ex-situ by XPS; (d) facile introduction of organometallic precursors, including liquid and solid sources with low vapor pressure—in HVP-CVD, they may be vaporized directly without heating or use of a carrier gas; (e) the high diffusion velocities enable large area uniformity and make the system insensitive to the geometry of metal precursor injection; (f) high vacuum diagnostics, such as QMS, may be used to study the chemistry directly-like MBE systems, HVP-CVD may be equipped with other high vacuum film characterization techniques (RHEED, HREELS, XPS, etc.) for in-situ analysis of film quality.

A Survey of Potential Metal Oxides and their Organometallic Precursors. Table I summarizes the leading high K dielectric candidates, as well as potential organometallic precursors. It should be appreciated that the table is not all inclusive of such dielectrics or organometallic precursors. The metal precursors used in CVD come in three basics flavors: metal alkyls, metal alkoxides, and complex β-diketonate structures.

The simplest organometallics are metal alkyls. However, even among these simple precursors, there are significant differences in their surface chemistry. For example, pyrolysis of precursors with ethyl ligands leads to less carbon incorporation than their methyl counterparts since its dehydrogenation products C₂H₄ and H₂ are all volatile. Another example is the difference between dimethyl and trimethyl species. The dimethyl compounds of Zn, Cd, and Te fully dissociate leaving free metal and methyl groups. In contrast, the trimethyl compounds of Ga, In, and Al decompose through dimethyl-metal and monomethyl-metal intermediates.

TABLE I
Comparison of relevant properties and precursors available for their synthesis.

| Metal | Dielectric | Band gap | Crystal | |
|---|---|---|---|---|
| Oxide | Constant (κ) | (eV) | Structure | Common Organometallic Precursors |
| SiO₂ | 3.8 | 8.9 | Amorphous | SiH₄, Si(OC₂H₅)₄ or TEOS |
| TiO₂ | 80 | 3.5 | Rutile | Ti(OC₃H₇)₄ or TTIP |
| ZrO₂ | 25 | 7.8 | Monoclinic | Zr(OC₄H₉)₄ or ZTB |
| HfO₂ | 25 | 5.7 | Monoclinic | Hf(OC₄H₉)₄ or HfTB |
| Al₂O₃ | 9 | 8.7 | Amorphous | [Al(CH₃)₃]₂ or TMA1, [Al(C₂H₅)₃]₂ or TEA1, |
| Ga₂O₃ | 12 | 4.9 | Amorphous | Ga(CH₃)₂ or TMG, Ga(C₂H₅)₃ or TEG |
| Y₂O₃ | 15 | 5.6 | Cubic | (C₁₁H₁₉O₂)₃Y or Y(dpm)₃ |
| | | | | Tris(2,2,6,6-tetramethylheptane-3,5- |
| | | | | dionate)yittrium or Y(THD)₃ |
| La₂O₃ | 30 | 4.3 | Cubic, hexagonal | Tris(2,2,6,6-tetramethylheptane-3,5- |
| | | | | dionate)lanthanum or La(THD)₃ |
| Ta₂O₅ | 26 | 4.5 | Orthorhombic | Ta(OC₂H₅)₅ |

The second class of candidates is the metal alkoxides, which have a chemical formula that may be represented by M(OR)ₙ. The most common of these is tetra-ethoxy silicon or TEOS, which has been used extensively for SiO₂ CVD. Alkoxy compounds are common precursors for many of the leading high K dielectrics including ZrO₂, TiO₂, HfO₂, and Ta₂O₅. The surface chemistry of the metal alkoxides has received considerably less study than the metal alkyls, and none in the presence of atomic oxygen. However, evidence from TEOS adsorption studies indicates that this class of precursors will also be promising for HVP-CVD. TEOS was observed to dissociate through a single bond cleavage on silicon at room temperature, forming an ethyl group and a triethoxysiloxane group. TEOS dissociation was also observed at low temperature (<200 K) on TiO₂, forming surface ethoxy groups. Of course, the behavior in the presence of atomic oxygen is expected to be much different. Nevertheless, the evidence of room temperature dissociation is very promising. A significant distinction of the metal alkoxides is that their decomposition can proceed either by breaking either the M-O bond or the O—C bond. In the TEOS examples cited above the M-O bond was broken for adsorption on TiO₂, while the O—C bond cleaved in the case of silicon. In the latter case, a metal oxide may be readily formed from the precursor itself. Indeed, metal alkoxides have been used for metal oxide CVD with no other oxidizer present.

The group IIIB oxides (Y₂O₃, La₂O₃) are more difficult to form by CVD due to lack of sufficiently volatile precursors. The rare earth species do form alkoxides, but their large, positively charged ionic radius of the metal atom causes these species to readily polymerize into compounds that have very low volatility. As such researchers have turned to the complex β-diketonate structures listed in Table I. These species are often solid sources that require heating to achieve sufficient volatility. One advantage of HVP-CVD over all other CVD techniques is its low pressure, which facilitates introduction of organometallics. The operating pressure is >1,000× less than any conventional thermal or plasma-enhanced CVD system.

Critical Issues in High K Dielectrics. In addition to a high κ value, there are numerous other considerations for dielectric applications that include thermodynamic stability with silicon, interface quality, and film morphology. In particular, Ti and Ta have been observed to be quite reactive with silicon. One approach to these interfacial issues has been to produce a thin (1-3 Å) SiO₂ buffer layer. Though successful, this limits the effectiveness of the high κ dielectric. HVP-CVD can address this issue in two ways. In R-PECVD high quality interfaces are produced in a two-step process. The silicon is first oxidized by exposure to atomic oxygen, followed by introduction of the metal precursor and deposition of the oxide. The same approach can be used in HVP-CVD. The second possibility is that interfacial reactions may not be an issue at the low substrate temperature that is enabled by HVP-CVD. In particular, the oxides of hafnia and zirconia are much more stable and do not require interfacial layers. High band gaps are also desirable, as these materials experience extremely high electric fields (>10⁷ V/cm) in gate applications.

Properties and Characterization. The influence of organometallic structure and oxide structure on the surface chemistry of metal oxide synthesis through HVP-CVD can be examined. The important metrics and the techniques that are used for evaluation are summarized here briefly: (a) Deposition rate:—This is measured by variable angle spectroscopic ellipsometry (VASE) and confirmed by cross-section SEM, TEM, and profilometry measurements. Primary control variable will be atomic oxygen flux, organometallic flux, and substrate temperature. (b) Dielectric Constant: The value may be inferred from the high frequency permittivity (ε_{∞}) obtained from VASE, and it can also be confirmed by fabrication of simple capacitors. (c) Carbon Incorporation: This is always a critical issue for gate dielectrics, and may be examined by transparency measurements of films grown on glass, as well as directly by XPS. (d) Film Structure & Morphology: Crystallinity and orientation can be assessed by XRD, surface morphlogy and roughness by AFM, and the interface structure of selected samples will be examined by cross-section SEM/TEM and angle-resolved XPS. (e) Band Gap: Optical absorption of films deposited on quartz are used to assess the band gap. (f) Chemistry Pathways: QMS are used to assess the chemistry in-situ as demonstrated in this proposal.

The foregoing description of the invention is intended to explain the best mode known of practicing the invention and to enable others skilled in the art to utilize the invention in various embodiments and with the various modifications required by their particular applications or uses of the invention.

What is claimed is:

1. An apparatus for use in producing a thin film on a substrate comprising:
a reactor vessel that defines a substantial portion of a thin film deposition chamber;
a support surface located within said vessel for supporting a target substrate;
a structure for providing an atomic reactive species to said chamber;
a port in said reactor vessel for conveying a volatile metal vapor into said chamber; and
a pump that is capable of producing a substantially collisionless environment in said chamber for gaseous substances.

2. An apparatus, as claimed in claim 1, wherein:
said pump is capable of producing a pressure in said chamber that is less than or equal to 1 mTorr.

3. An apparatus, as claimed in claim 1, wherein:
said pump is capable of producing a pressure in said chamber of less than or equal to 100 pTorr.

4. An apparatus, as claimed in claim 1, wherein:
said pump is capable of producing a pressure in said chamber of less than or equal to 10 pTorr.

5. An apparatus, as claimed in claim 1, wherein:
said structure adapted to effuse atomic oxygen from an interior space associated with said structure to said chamber during operation.

6. An apparatus for use in producing a thin film on a substrate comprising:
a reactor vessel that defines a substantial portion of a thin film deposition chamber;
a support surface located within said vessel for supporting a target substrate;
a structure for providing a reactive species from an interior space associated with said structure to said chamber, said structure and said vessel adapted such that, during operation, a pressure ratio of said interior space to said chamber is such that said interior space is substantially decoupled from said chamber;
a first port in said reactor vessel for conveying a volatile metal vapor into said chamber;
a second port for communicating with a pump that is capable of producing a low pressure environment in said chamber for gaseous substances.

7. An apparatus, as claimed in claim 6, wherein:
said structure comprises a vessel with an interior space and an exit structure for passing atomic oxygen from said interior space into said chamber.

8. An apparatus, as claimed in claim 7, wherein:
said exit structure comprising a hole structure adapted so that, during operation, said interior space of said vessel is capable of being maintained at a substantially higher pressure than said chamber.

9. An apparatus, as claimed in claim 6, wherein:
said structure comprises an inductively-coupled plasma generator.

10. An apparatus, as claimed in claim 6, wherein:
said structure comprises a capacitively-coupled plasma generator.

11. An apparatus, as claimed in claim 6, wherein:
said structure comprises a photolysis plasma generator.

12. An apparatus, as claimed in claim 6, wherein:
said structure comprises a thermal plasma generator.

13. An apparatus, as claimed in claim 6, wherein:
said structure comprises a thermal source.

14. An apparatus, as claimed in claim 6, wherein:
said structure comprises a photolysis source.

15. An apparatus for use in producing a thin film on a substrate comprising:
a reactor vessel that defines a thin film deposition chamber;
a support surface located within said vessel for supporting a target substrate;
a structure for providing a reactive species from an interior space associated with said structure to said chamber, said structure and said vessel adapted such that, during operation, said interior space and said chamber have a pressure differential such that said interior space is substantially decoupled from said chamber;
a port in said reactor vessel for conveying a volatile metal vapor into said chamber;
a pump that is capable of producing a pressure in said chamber of less than about 1 mTorr;
a monitoring system for assessing the performance of at least one other element of the apparatus.

16. An apparatus, as claimed in claim 15, wherein:
said monitoring system comprises a reactive species monitoring system.

17. An apparatus, as claimed in claim 15, wherein:
said reactive species monitoring system comprises an optical emission spectrometer.

18. An apparatus, as claimed in claim 15, wherein:
said monitoring system comprises a composition monitoring system for monitoring the composition of the constituents within the chamber.

19. An apparatus, as claimed in claim 18, wherein:
said composition monitoring system comprises a mass spectrometer.

20. An apparatus, as claimed in claim 15, further comprising:
a heater for providing heat to said support surface to heat a substrate located adjacent to said support surface during operation.

21. A method for producing a thin film comprising:
providing a reactor vessel that defines a chamber, a substrate onto which a thin film is to be deposited that is located within said chamber, and a pressure within said chamber such that said chamber is a substantially collisionless environment for gaseous substances located within said chamber; and
injecting a volatile metal vapor and a reactive species into said chamber such that said volatile metal vapor and said reactive species are present in said chamber at the same time and such that a thin film is deposited on said substrate.

22. A method, as claimed in claim 21, wherein:
said step of providing comprises providing temperature control of said substrate.

23. A method, as claimed in claim 22, wherein:
said step of providing temperature control to said substrate such that said substrate has a temperature suitable for establishment of a thin film and about 100° C. less than the temperature for producing a comparable thin film in a plasma enhanced chemical vapor deposition system.

24. A method, as claimed in claim 21, wherein
said chamber has a pressure less than or equal to 1 mTorr.

25. A method, as claimed in claim 21, wherein:
said chamber has a pressure in the range of 50 μTorr to 1 mTorr.

26. A method, as claimed in claim 21, wherein:
said step of injecting comprises moving a reactive species from a space with a pressure that is about 10 times greater than a pressure within said chamber.

27. A method, as claimed in claim 21, wherein:
said step of injecting comprises injecting a dopant material into said chamber.
